(19) United States
(12) Patent Application Publication
(10) Pub. No.: US 2012/0075812 A1
(43) Pub. Date: Mar. 29, 2012

(54) MULTI-CHIP PACKAGE

(75) Inventor: Wolfram Hable, Neumarkt (DE)

(73) Assignee: INFINEON TECHNOLOGIES AG, Neubiberg (DE)

(21) Appl. No.: 13/241,334

(22) Filed: Sep. 23, 2011

(30) Foreign Application Priority Data
Sep. 29, 2010 (DE) 102010046963.7

(51) Int. Cl. H05K 7/00

(52) U.S. Cl. 361/746; 361/728

(57) ABSTRACT

In various embodiments, a chip module may include a substrate; electronic components, the electronic components being arranged on a first side of the substrate; and an insulating layer, which is applied to the first side of the substrate and to the electronic components, contact openings being arranged in the insulating layer which permit electrical contacting of the electronic components; and an electrically conducting layer being arranged on the insulating layer and in the contact openings, which connects the electronic components electrically to one another.

### CROSS-REFERENCE TO RELATED APPLICATION

This application claims priority to German Patent Application Serial No. 10 2010 046 963.7, which was filed Sep. 29, 2010, and is incorporated herein by reference in its entirety.

### TECHNICAL FIELD

Various embodiments relate to an efficient interconnection of a number of electrical components to form a multi-chip module.

### BACKGROUND

Previously, the interconnection of a number of electrical components or chips on a substrate to form a multi-chip module was realized by means of wire connections using what is known as the wire bonding method. This involves connecting the electrical contacts on the upper sides of the chips to contact areas on the substrate or to contact areas on other chips. Particularly suitable as materials for the wired connection are gold, aluminum and copper. A disadvantage of this wire bonding technology is the restricted reliability of this connecting technology, and there is consequently the possibility of the entire component failing. Furthermore, wire bonding is a serial process, which takes a relatively long time and is consequently expensive. Moreover, the space requirement to allow the connections to be produced is not inconsiderable. The wire bonding technology consequently prevents the component size from being optimized.

One possibility of solving this problem is, for example, to bond aluminum wires that are up to 330 μm thick by means of ultrasound as a connection between the chip contact points and other connecting elements on a DCB ceramic, preferably in a multiply parallel way. DCB ceramic stands for Direct Copper Bonding ceramic and refers to a process in which copper and ceramic material are fused together at high temperatures. DCB ceramics offer the advantage of high mechanical stability with at the same time excellent thermal and electrical conductivity and good heat conduction. However, the desirable optimum long-term stability cannot be achieved with this technique since, for example, cracks may occur at the bonding points. By contrast, DE 3119239 A1 describes a multi-layer structure of large-scale integration (LSI) semiconductor components. By virtue of very low stresses and differences in stress between individual internal interconnections, here there is no requirement for mutual insulation of the individual contact lines or electrical connections from one another.

### SUMMARY

In various embodiments, a chip module may include a substrate; electronic components, the electronic components being arranged on a first side of the substrate; and an insulating layer, which is applied to the first side of the substrate and to the electronic components, contact openings being arranged in the insulating layer which permit electrical contacting of the electronic components; and an electrically conducting layer being arranged on the insulating layer and in the contact openings, which connects the electronic components electrically to one another.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an embodiment of a chip module in cross section;

FIG. 2 shows a multi-chip module using wire bonding technology;

FIG. 3 shows various embodiments of a chip module in plan view; and

FIG. 4 shows various embodiments of a chip module in cross section.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments provide an efficient and inexpensive interconnection of a number of components.

Various embodiments of a chip module include a substrate, and electronic components, the electronic components being arranged on a first side of the substrate. Furthermore, the chip module may include an insulating layer, which is applied to the first side of the substrate and to the electronic components, there being arranged in the insulating layer contact openings which permit electrical contacting of the electronic components and there being arranged on the insulating layer and in the contact openings an electrically conducting layer, which connects the electronic components electrically to one another. As a result, the probability of failure of the chip module may be reduced and the reliability of the chip module may be increased. The chip module described may also have the effect that the production costs are considerably lower.

In various embodiments of the chip module, the electrically conducting layer is deposited on the insulating layer by means of a galvanic process. This process may offer the advantage that it represents the state of the art in production and is therefore quick and inexpensive.

In various embodiments of the chip module, the electronic components are connected to one another by means of a further electrically conducting layer applied to the substrate. This allows the electronic components to be applied directly to a DCB ceramic, and this ensures inexpensive production, since DCB ceramic is commercially available everywhere.

In various embodiments of the chip module, the conducting layer and the further conducting layer are electrically connected to one another by means of the contact openings. This may offer the advantage over bonding technology that the electronic components can be contacted as desired from both sides and at the same time increases the reliability of the chip module.

In various embodiments, the substrate of the chip module includes a DCB ceramic. DCB ceramics are easily and inexpensively available from specialist retailers and can be easily and inexpensively processed in production. DCB ceramics may offer the advantage over conventional substrates that they are very stable and have outstanding insulating and heat-conducting properties.

In various embodiments of the chip module, the insulating layer includes epoxy resin. Epoxy resin is processed as a good and inexpensive insulator in the production of the semiconductor industry.

In various embodiments, the insulating layer of the chip module includes glass fibers and/or filling particles. This may allow the insulating layer to be reinforced and leads to an altogether better stability of the module as a whole.

In various embodiments, the insulating layer is connected to the substrate by means of lamination. Lamination is used, inter alia, in housing production as an inexpensive and quick connecting technology.

In various embodiments, electrical contacts for contacting the chip module are arranged on the conducting layer of the chip module. This may offer the advantage that the chip module can be electrically contacted very easily from the outside.

In various embodiments, the electrical contacts are connected to the conducting layer by means of solder. Soldered connections may ensure a very good electrical connection and are easy and quick to produce.

In various embodiments, the chip module is at least partially encapsulated with molding compound. The molding compound may ensure the high overall stability of the chip module and prevents the electronic components from breaking up during the aging process.

In various embodiments, the electronic components are connected to the DCB ceramic by means of solder. Soldered connections may ensure a very good electrical connection and can be realized easily and inexpensively.

Various embodiments are explained in more detail below, with reference to the accompanying figures. However, the invention is not restricted to the embodiments actually described, but may be modified and altered in a suitable way. It is within the scope of the invention to suitably combine individual features and combinations of features of one embodiment with features and combinations of features of another embodiment in order to arrive at further embodiments according to the invention.

Before the exemplary embodiments of the present invention are explained in more detail on the basis of the figures, it is pointed out that the same elements in the figures are provided with the same or similar designations and that these elements are only described once. Furthermore, the figures are not necessarily to scale. Rather, emphasis is placed on explaining the basic principle.

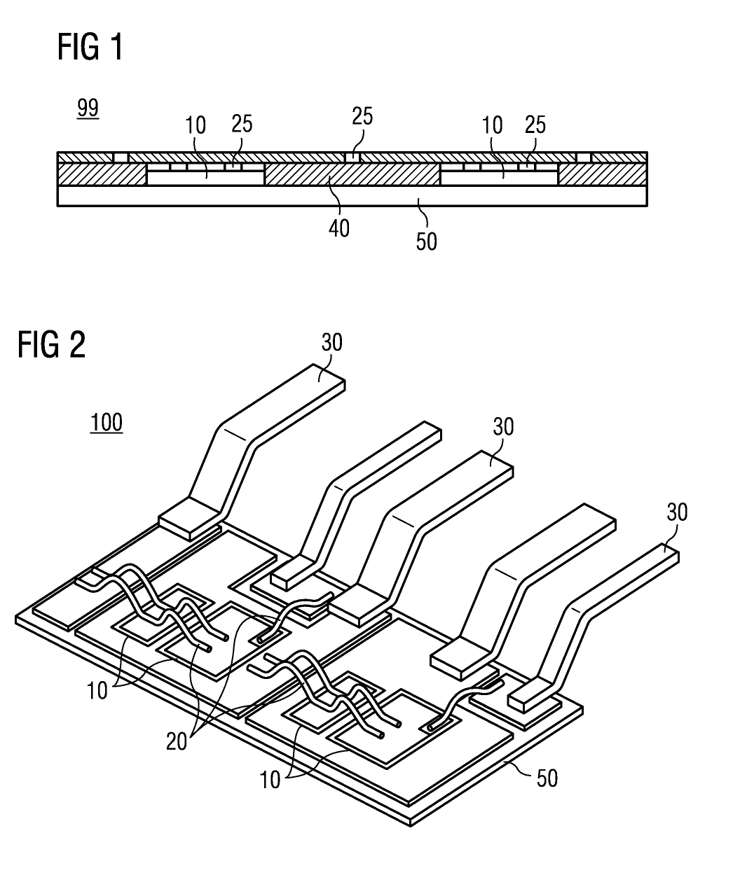

FIG. 1 shows a multi-chip module 99. In various embodiments, the chips 10 are arranged on one side of a substrate 50. The substrate may include ceramic. The electronic components 10, for example integrated circuits, chips or transistors, are arranged on the substrate 50, 60. Here, the electronic components could also be, for example, what are known as bare dies, which do not have any housing and are then processed further. The electronic components 10 are in various embodiments connected here to the substrate, preferably DCB ceramic, by means of solder or else by means of nanopaste. A thin insulating layer 40 is applied to the DCB ceramic 50 and the electronic component. The insulating layer 40 in various embodiments includes epoxy resin and may be reinforced with glass fibers and/or filling particles. Contact holes 25, also referred to as vias, are drilled into this insulating layer 40 by a laser or an etching technique. A conductive layer 25 is deposited on the insulating layer 40, in various embodiments using a galvanic process. The conducting layer 25 may in various embodiments include copper. The electrodeposition also causes the vias to be filled with copper. The two chips are electrically connected to one another by means of the conducting layer and the vias.

FIG. 2 shows a multi-chip module 100. In various embodiments, four chips 10 are arranged on a conducting substrate 50. The chips 10 are connected to one another by means of bonding wires 20. Furthermore, 10 contacts 30 are arranged for the electrical contracting of the chips from the outside.

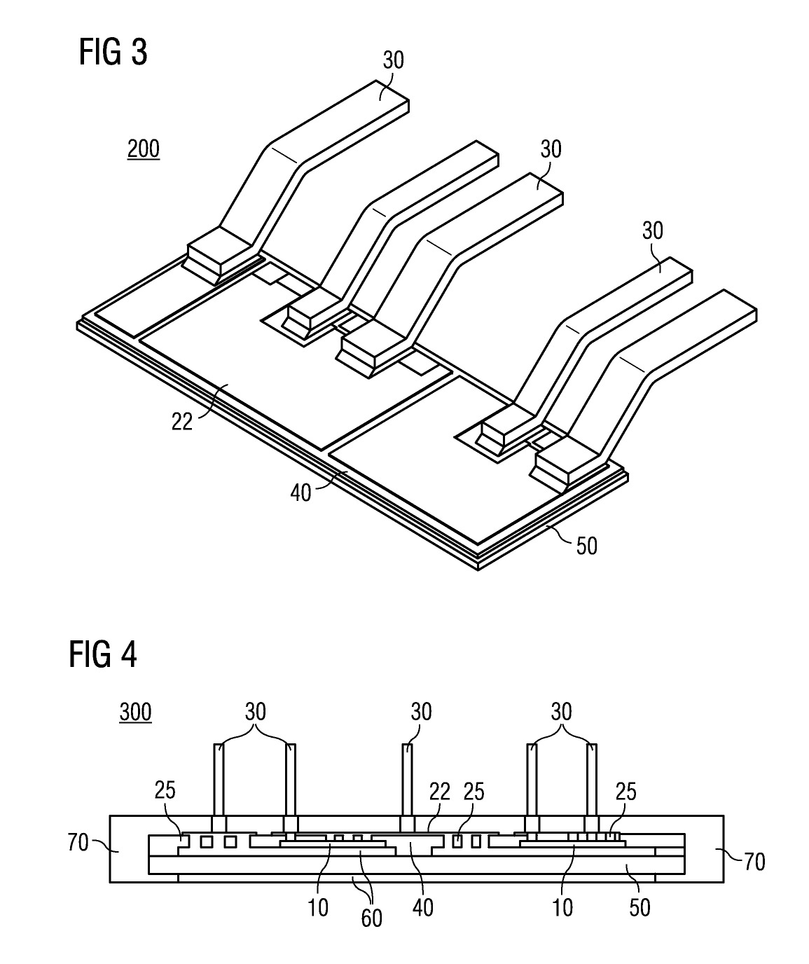

FIG. 3 shows various embodiments of a multi-chip module 200. In this view, the chips 10 themselves cannot be seen, since they are covered by a conducting layer 22. The chips are arranged on a substrate 50 and a conducting layer. At the edge of the chip module, an insulating layer 40 can be seen. The multi-chip module may be electrically contacted by means of contacts 30.

FIG. 4 shows various embodiments of a multi-chip module 300 reproduced as shown in FIG. 1. In various embodiments, the chips 10 are arranged on one side of a substrate 50 and in various embodiments form what is known as a half-bridge circuit. Half-bridge circuits may be used e.g. for the driving of inductive loads, such as for example electric motors. The substrate may in various embodiments include ceramic—on which in various embodiments two conducting layers are arranged. The conducting layers 60 may in various embodiments include copper. The electronic components 10, for example integrated circuits, chips or transistors, are arranged on the substrate 50, 60. Here too, bare dies, which do not have any housing, are in various embodiments connected to form a multi-chip module. Here, the electronic components 10 are in various embodiments connected to the substrate, in various embodiments DCB ceramic, by means of solder or else by means of nanopaste. A thin insulating layer 40 is applied to the DCB ceramic 50, 60 and the electronic component. The insulating layer 40 in various embodiments include epoxy resin and may be reinforced with glass fibers and/or filling particles. Contact holes 25, also referred to as vias, are drilled into this insulating layer 40 by a laser or an etching technique. A conductive layer 25 is deposited on the insulating layer 40, in various embodiments using a galvanic process. The conducting layer 25 may in various embodiments include copper. The electrodeposition also causes the vias to be filled with copper. Subsequently, the conducting layer 25 may be structured in accordance with the intended circuit by means of etching or lasering. The electronic components may be contacted and electrically connected to one another by means of the conducting layer and the vias. Electrical contacts 30 for the contacting of the chip module are then arranged on the conducting layer from the outside. The electrical contacts may likewise be soldered. In a further step, the chip module is encapsulated with molding compound 70 (molded).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip module, comprising:
a substrate;
electronic components, the electronic components being arranged on a first side of the substrate; and
an insulating layer, which is applied to the first side of the substrate and to the electronic components,
contact openings being arranged in the insulating layer which permit electrical contacting of the electronic components; and
an electrically conducting layer being arranged on the insulating layer and in the contact openings, which connects the electronic components electrically to one another.

2. The chip module as claimed in claim 1,
wherein the electrically conducting layer is deposited on the insulating layer by means of electrodeposition.

3. The chip module as claimed in claim 1,
wherein the electronic components is connected to one another by means of a further electrically conducting layer applied to the substrate.

4. The chip module as claimed in claim 3,
wherein the conducting layer and the further conducting layer are electrically connected to one another by means of the contact openings.

5. The chip module as claimed in claim 1,
wherein the substrate comprises a DCB ceramic.

6. The chip module as claimed in claim 1,
wherein the insulating layer comprises epoxy resin.

7. The chip module as claimed in claim 1,
wherein the insulating layer comprises at least one of glass fibers and filling particles.

8. The chip module as claimed in claim 1,
wherein the insulating layer is connected to the substrate by means of lamination.

9. The chip module as claimed in claim 1,
wherein the electrical contacts for the contacting of the chip module are arranged on the conducting layer.

10. The chip module as claimed in claim 9,
wherein the electrical contacts are connected to the conducting layer by means of solder.

11. The chip module as claimed in claim 1,
wherein the chip module is at least partially encapsulated with molding compound.
